(19) United States
(12) Patent Application Publication
(10) Pub. No.: US 2006/0084224 A1
(43) Pub. Date: Apr. 20, 2006

(54) Semiconductor device and method of fabricating the same

(76) Inventors: Shinya Watanabe, Tokyo (JP); Jun Idebuchi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/245,177

(22) Filed: Oct. 7, 2005

(30) Foreign Application Priority Data
Oct. 18, 2004 (JP) 2004-303100

(51) Int. Cl. H01L 21/8242

(52) U.S. Cl. 438/243; 438/244; 438/248

(57) ABSTRACT

According to the present invention, there is provided a semiconductor devise comprising: a gate electrode formed via a gate insulating film selectively formed on a predetermined region of a semiconductor substrate; a source region and drain region formed in a surface portion of said semiconductor substrate on two sides of a channel region positioned below said gate electrode; a capacitor insulating film formed in the surface portion of said semiconductor substrate to cover an inner surface near a bottom portion of a trench formed adjacent to one of said source region and drain region; a capacitor electrode formed to be buried in said trench covered with said capacitor insulating film; an insulating film formed to cover an inner surface of said trench, which is not covered with said capacitor insulating film; a conductive layer containing a predetermined impurity and formed in said trench so as to be buried in a portion covered with said insulating film on said capacitor electrode; a surface connecting layer formed on the surface of said semiconductor substrate to electrically connect said conductive layer and one of said source region and drain region; and an impurity diffusion inhibiting film formed to cover the inner surface of said trench to a predetermined depth from an interface between said surface connecting layer and conductive layer, and having a film thickness smaller than that of said insulating film.

### CROSS REFERENCE TO RELATED APPLICATION

This application is based upon and claims benefit of priority under 35 USC §119 from the Japanese Patent Application No. 2004-303100, filed on Oct. 18, 2004, the entire contents of which are incorporated herein by reference.

### BACKGROUND OF THE INVENTION

The present invention relates to a semiconductor device and a method of fabricating the same.

A memory cell of a DRAM includes one transistor and one capacitor. Recently, to reduce the dimensions of the capacitor of this DRAM memory cell while maintaining the capacitance of the capacitor, a trench capacitor type DRAM memory cell in which a capacitor is formed in the direction of depth of a semiconductor substrate is developed.

In this trench capacitor type DRAM memory cell, a trench is formed in the surface of a semiconductor substrate, and an insulating film is formed on the inner surfaces of the lower portion of this trench. After that, arsenic-doped polysilicon which is polysilicon in which arsenic (As) is doped is buried in the trench, thereby forming a trench capacitor which uses the semiconductor substrate and arsenic-doped polysilicon as an electrode.

In addition, after an insulating film called a collar oxide film is formed on the inner surfaces of the upper portion of the trench, arsenic-doped polysilicon is further buried in this trench to form a conductive layer.

Also, a MOS transistor is formed on the semiconductor substrate, and a drain region of this MOS transistor is formed in the surface portion of the semiconductor substrate so as to be adjacent to the collar oxide film. Furthermore, on the surface of the semiconductor substrate, a conductive layer called a surface strap is formed to electrically connect the drain region of the MOS transistor and the conductive layer formed in the trench.

In this trench capacitor type memory cell having the above structure, an electric current flows between the drain region of the MOS transistor and the trench capacitor via the surface strap formed on the semiconductor substrate surface and the conductive layer formed in the trench in order.

Note that an element isolation insulating film for isolating adjacent trench capacitors is formed near the upper portion of the trench.

Since the collar oxide film is formed on the inner surfaces of the upper portion of the trench, the area of the interface in which the surface strap formed on the semiconductor substrate surface and the conductive layer formed in the trench are in contact with each other decreases by the film thickness of this collar oxide film. This poses the problem that the resistance of the interface increases.

One method of reducing the resistance of the interface is to increase the area of the interface between the surface strap and the conductive layer by partially removing the collar oxide film formed near this interface.

In this method, however, when annealing for forming, e.g., a source region and drain region is performed after the trench capacitor and conductive layer are formed in the trench, arsenic diffuses into the semiconductor substrate from the arsenic-doped polysilicon forming the conductive layer in the trench, thereby forming an impurity diffusion layer whose junction depth is larger than that of the drain region of the MOS transistor.

This decreases the gate threshold voltage of the MOS transistor, and causes a short-channel effect which increases a leakage current between the source region and drain region.

A reference concerning the trench capacitor is as follows.

Japanese Patent Laid-Open No. 11-214651

### SUMMARY OF THE INVENTION

According to one aspect of the invention, there is provided a semiconductor device comprising:

a gate electrode formed via a gate insulating film selectively formed on a predetermined region of a semiconductor substrate;

a source region and drain region formed in a surface portion of said semiconductor substrate on two sides of a channel region positioned below said gate electrode;

a capacitor insulating film formed in the surface portion of said semiconductor substrate to cover an inner surface near a bottom portion of a trench formed adjacent to one of said source region and drain region;

a capacitor electrode formed to be buried in said trench covered with said capacitor insulating film;

an insulating film formed to cover an inner surface of said trench, which is not covered with said capacitor insulating film;

a conductive layer containing a predetermined impurity and formed in said trench so as to be buried in a portion covered with said insulating film on said capacitor electrode;

a surface connecting layer formed on the surface of said semiconductor substrate to electrically connect said conductive layer and one of said source region and drain region; and

an impurity diffusion inhibiting film formed to cover the inner surface of said trench to a predetermined depth from an interface between said surface connecting layer and conductive layer, and having a film thickness smaller than that of said insulating film.

According to one aspect of the invention, there is provided a semiconductor device comprising:

a gate electrode formed via a gate insulating film selectively formed on a predetermined region of a semiconductor substrate;

a source region and drain region formed in a surface portion of said semiconductor substrate on two sides of a channel region positioned below said gate electrode;

an insulating film formed in the surface portion of said semiconductor substrate to cover an inner surface of a trench formed adjacent to one of said source region and drain region, except for a portion near the surface of said semiconductor substrate and a portion near a bottom portion of said trench;

an impurity diffusion inhibiting film formed to cover the inner surface of said trench and said insulating film, and having a film thickness smaller than that of said insulating film;

a conductive layer containing a predetermined impurity and formed to be buried in said trench in which said impurity diffusion inhibiting film is formed; and

a surface connecting layer formed on the surface of said semiconductor substrate to electrically connect said conductive layer and one of said source region and drain region.

According to one aspect of the invention, there is provided a semiconductor device fabrication method comprising:

forming a trench by removing a desired region of a surface portion of a semiconductor substrate;

forming a capacitor insulating film to cover an inner surface near a bottom portion of the trench;

forming a film by depositing a conductive material containing a first impurity so as to fill the trench covered with the capacitor insulating film, thereby forming a capacitor electrode;

forming an insulating film so as to cover an inner surface of the trench, which is not covered with the capacitor insulating film;

forming, in the trench, a film by depositing the conductive material containing a second impurity so as to fill a portion covered with the insulating film on the capacitor electrode, thereby forming a first conductive layer;

forming an impurity diffusion inhibiting film having a film thickness smaller than that of the insulating film, so as to cover an inner surface of the trench near the surface of the semiconductor substrate;

forming, in the trench, a film by depositing the conductive material containing a third impurity so as to fill a portion covered with the impurity diffusion inhibiting film on the first conductive layer, thereby forming a second conductive layer;

forming a gate electrode on a predetermined region of the semiconductor substrate via a gate insulating film;

forming a source region and drain region in the surface portion of the semiconductor substrate, such that one of the source region and drain region is adjacent to the trench; and

forming, on the surface of the semiconductor substrate, a surface connecting layer which electrically connects the second conductive layer and one of the source region and drain region.

According to one aspect of the invention, there is provided a semiconductor device fabrication method comprising:

forming a trench by removing a desired region of a surface portion of a semiconductor substrate;

sequentially forming first and second films so as to cover an inner surface of the trench;

forming a first resist film having a desired height from a bottom portion of the trench by coating a first resist material so as to fill the trench in which the first and second films are formed;

removing the second film having an exposed surface, and removing the first resist film remaining in the trench;

forming a first insulating film by oxidizing the first film having an exposed surface;

sequentially removing the second and first films remaining in the trench;

forming a second resist film lower than the surface of the semiconductor substrate by coating a second resist material so as to fill the trench in which the first insulating film is formed;

removing the first insulating film having an exposed surface;

removing the second resist film remaining in the trench;

forming a second insulating film having a film thickness smaller than that of the first insulating film, on the inner surface of the trench and on the surface of the first insulating film;

forming a film by depositing a conductive material containing a predetermined impurity so as to fill the trench in which the first and second insulating films are formed, thereby forming a conductive layer;

forming a gate electrode on a predetermined region of the semiconductor substrate via a gate insulating film;

forming a source region and drain region in the surface portion of the semiconductor substrate, such that one of the source region and drain region is adjacent to the trench; and

forming, on the surface of the semiconductor substrate, a surface connecting layer which electrically connects the conductive layer and one of the source region and drain region.

### BRIEF DESCRIPTION OF THE DRAWINGS

FIG. 1 is a longitudinal sectional view showing the sectional structure of a device in a predetermined step of a semiconductor device fabrication method according to the first embodiment of the present invention;

FIG. 2 is a longitudinal sectional view showing the sectional structure of a device in a predetermined step of the semiconductor device fabrication method;

FIG. 3 is a longitudinal sectional view showing the sectional structure of a device in a predetermined step of the semiconductor device fabrication method;

FIG. 4 is a longitudinal sectional view showing the sectional structure of a device in a predetermined step of the semiconductor device fabrication method;

FIG. 5 is a longitudinal sectional view showing the sectional structure of a device in a predetermined step of the semiconductor device fabrication method;

FIG. 6 is a longitudinal sectional view showing the sectional structure of a device in a predetermined step of the semiconductor device fabrication method;

FIG. 7 is a longitudinal sectional view showing the sectional structure of a device in a predetermined step of the semiconductor device fabrication method;

FIG. 8 is a longitudinal sectional view showing the sectional structure of a device in a predetermined step of the semiconductor device fabrication method;

FIG. 9 is a longitudinal sectional view showing the sectional structure of a device in a predetermined step of the semiconductor device fabrication method;

FIG. 10 is a longitudinal sectional view showing the sectional structure of a device in a predetermined step of the semiconductor device fabrication method;

FIG. 11 is a longitudinal sectional view showing the sectional structure of a device in a predetermined step of the semiconductor device fabrication method;

FIG. 12 is a longitudinal sectional view showing the sectional structure of a device in a predetermined step of a semiconductor device fabrication method according to the second embodiment of the present invention;

FIG. 13 is a longitudinal sectional view showing the sectional structure of a device in a predetermined step of the semiconductor device fabrication method;

FIG. 14 is a longitudinal sectional view showing the sectional structure of a device in a predetermined step of the semiconductor device fabrication method;

FIG. 15 is a longitudinal sectional view showing the sectional structure of a device in a predetermined step of the semiconductor device fabrication method;

FIG. 16 is a longitudinal sectional view showing the sectional structure of a device in a predetermined step of a semiconductor device fabrication method according to the third embodiment of the present invention;

FIG. 17 is a longitudinal sectional view showing the sectional structure of a device in a predetermined step of the semiconductor device fabrication method;

FIG. 18 is a longitudinal sectional view showing the sectional structure of a device in a predetermined step of the semiconductor device fabrication method;

FIG. 19 is a longitudinal sectional view showing the sectional structure of a device in a predetermined step of the semiconductor device fabrication method;

FIG. 20 is a longitudinal sectional view showing the sectional structure of a device in a predetermined step of a semiconductor device fabrication method according to the fourth embodiment of the present invention;

FIG. 21 is a longitudinal sectional view showing the sectional structure of a device in a predetermined step of the semiconductor device fabrication method;

FIG. 22 is a longitudinal sectional view showing the sectional structure of a device in a predetermined step of the semiconductor device fabrication method;

FIG. 23 is a longitudinal sectional view showing the sectional structure of a device in a predetermined step of the semiconductor device fabrication method;

FIG. 24 is a longitudinal sectional view showing the sectional structure of a device in a predetermined step of the semiconductor device fabrication method;

FIG. 25 is a longitudinal sectional view showing the sectional structure of a device in a predetermined step of the semiconductor device fabrication method; and

FIG. 26 is a longitudinal sectional view showing the sectional structure of a device in a predetermined step of the semiconductor device fabrication method.

### DETAILED DESCRIPTION OF THE INVENTION

Embodiments of the present invention will be described below with reference to the accompanying drawings.

### (1) First Embodiment

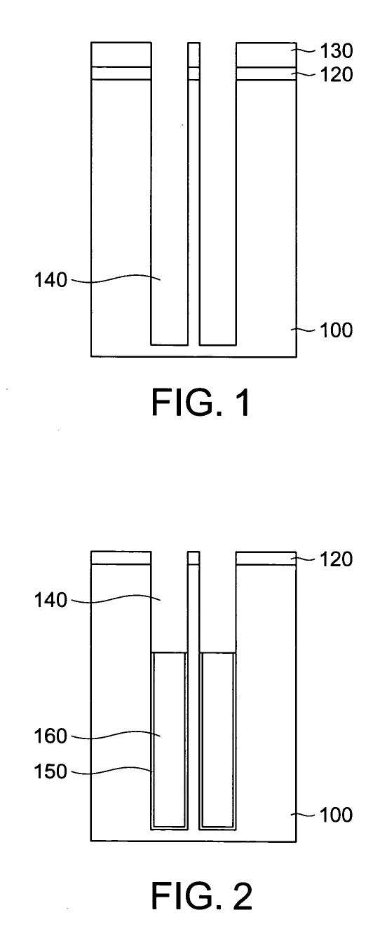

FIGS. 1 to 11 show a method of fabricating a memory cell of a trench capacitor type DRAM according to the first embodiment of the present invention. First, as shown in FIG. 1, LPCVD (Low Pressure Chemical Vapor Deposition) is used to form a silicon oxide (SiO₂) film (not shown) about 2 nm thick on a semiconductor substrate 100, form a silicon nitride (SiN) film 120 about 220 nm thick, and form a BSG film 130 about 1,600 nm thick which is a silicon oxide film in which boron (B) is doped.

The BSG film 130, silicon nitride (SiN) film 120, and silicon oxide (SiO₂) film (not shown) are sequentially patterned by lithography and RIE (Reactive Ion Etching). Then, the BSG film 130 is used as a mask to etch the semiconductor substrate 100, thereby forming trenches (DTs) 140 about 8 μm deep from the surface of the semiconductor substrate 100.

As shown in FIG. 2, after the BSG film 130 is removed by wet etching, an NO film 150 about 5 nm thick which is a stacked film of a silicon nitride (SiN) film and silicon oxide (SiO₂) film is formed on the entire surfaces of the semiconductor substrate 100 and silicon nitride (SiN) film 120 by LPCVD. In addition, arsenic-doped polysilicon which is polysilicon as a conductive material in which arsenic (As) is doped as an impurity is deposited on the entire surface, thereby forming an arsenic-doped polysilicon film 160 about 200 nm thick. Note that it is also possible to dope another impurity such as phosphorus (P), instead of arsenic (As).

The arsenic-doped polysilicon film 160 is then removed by RIE to a depth of about 1 μm from the surface of the semiconductor substrate 100. After that, the NO film 150 which is exposed by the removal of the arsenic-doped polysilicon film 160 is removed by wet etching.

In this manner, a capacitor insulating film made of the NO film 150 is formed, and capacitor electrodes made of the arsenic-doped polysilicon film 160 as a conductive layer are formed, thereby forming trench capacitors made of the semiconductor substrate 100, NO film 150, and arsenic-doped polysilicon film 160.

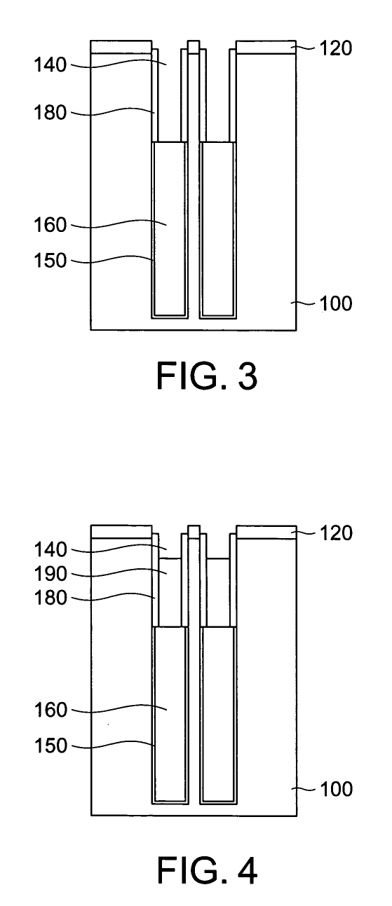

As shown in FIG. 3, a silicon oxide (SiO₂) film (not shown) about 8 nm thick is formed on the entire inner surfaces of the exposed trenches 140 and on the entire surface of the arsenic-doped polysilicon film 160. On the entire surface of this silicon oxide (SiO₂) film (not shown), a collar oxide film 180 about 35 nm thick made of, e.g., a silicon oxide (SiO₂) film is formed by LPCVD. After that, an insulating film made of the collar oxide film 180 is formed on the inner surfaces of the upper portions of the trenches 140 by RIE.

As shown in FIG. 4, arsenic-doped polysilicon is deposited on the entire surfaces of the arsenic-doped polysilicon film 160, collar oxide film 180, and silicon nitride (SiN) film 120 to form a arsenic-doped polysilicon film 190 about 200 nm thick. After that, the arsenic-doped polysilicon film 190 is removed by RIE to a depth of about 100 nm from the surface of the semiconductor substrate 100, thereby forming a conductive layer made of the arsenic-doped polysilicon film 190.

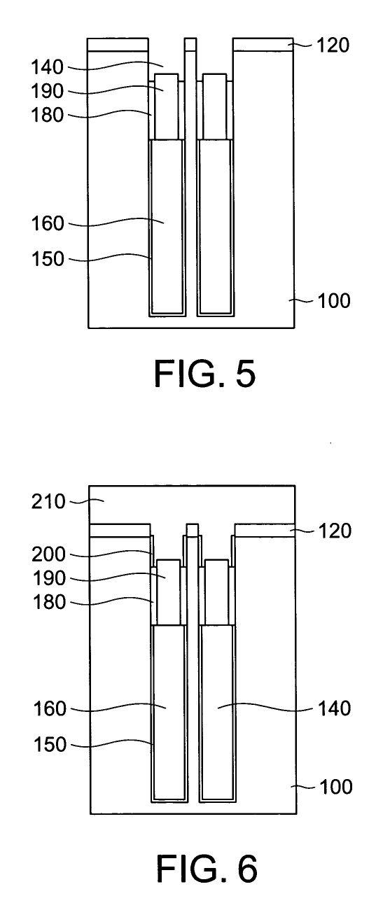

As shown in FIG. 5, the collar oxide film 180 is removed by wet etching to a depth of about 80 nm from the surface of the arsenic-doped polysilicon film 190.

As shown in FIG. 6, a silicon nitride (SiN) film 200 about 2 to 7 nm thick is formed by LPCVD on the entire surfaces of the collar oxide film 180, arsenic-doped polysilicon film 190, and silicon nitride (SiN) film 120. After that, an impurity diffusion inhibiting film made of the silicon nitride (SiN) film 200 is formed on the inner surfaces of the upper portions of the trenches 140 by RIE.

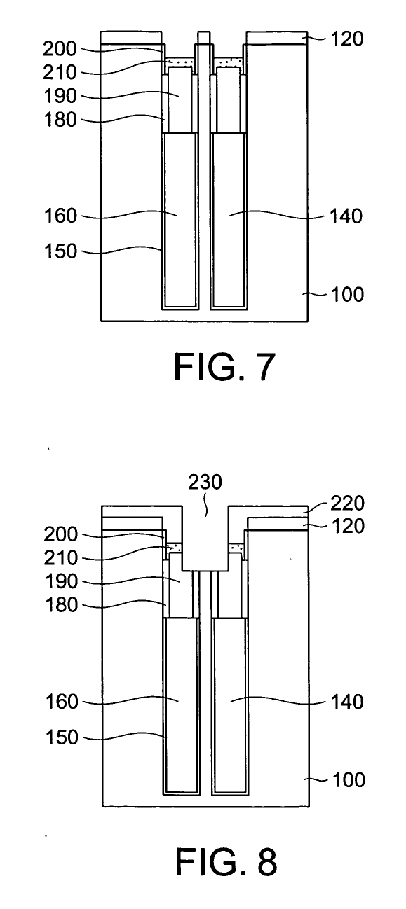

An arsenic-doped polysilicon film 210 is formed by depositing arsenic-doped polysilicon about 200 nm thick on the entire surfaces of the collar oxide film 180, silicon nitride (SiN) film 200, arsenic-doped polysilicon film 190, and silicon nitride (SiN) film 120. As shown in FIG. 7, the arsenic-doped polysilicon film 210 is removed by RIE to a depth of about 30 nm from the surface of the semiconductor substrate 100, thereby forming a conductive layer made of the arsenic-doped polysilicon film 210.

As shown in FIG. 8, a silicon oxide (SiO₂) film 220 about 250 nm thick is deposited, and a trench 230 about 300 nm deep from the surface of the semiconductor substrate 100 is formed by lithography and RIE.

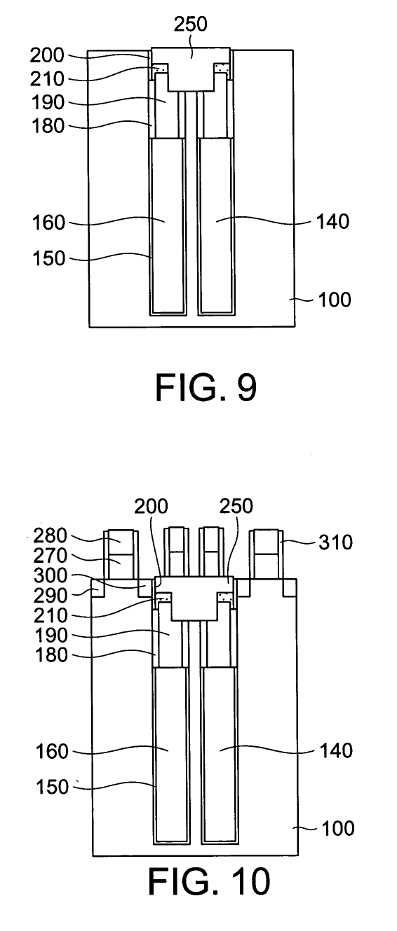

As shown in FIG. 9, the silicon oxide (SiO₂) film 220 is remove by wet etching, and a thermal oxide film (not shown) about 4 nm thick made of a silicon oxide (SiO₂) film is formed on the entire surface. After that, a silicon oxide (SiO₂) film 250 about, e.g., 400 nm thick is formed on the entire surface of the thermal oxide film.

Then, the silicon oxide (SiO₂) film 250 formed in a position higher than the surface of the silicon nitride (SiN) 120 is removed by planarization. In addition, the silicon oxide (SiO₂) film 250 is removed by wet etching to a height of about 30 nm from the surface of the semiconductor substrate 100.

The silicon nitride (SiN) film 120 is removed by wet etching to form an STI (Shallow Trench Isolation) film 250 as an element isolation insulating film for electrically isolating adjacent trench capacitors.

As shown in FIG. 10, a silicon oxide (SiO₂) film (not shown) about 2.5 nm thick, for example, is formed on the surface of the semiconductor substrate 100. After that, a phosphorus-doped polysilicon film 270 about 200 nm thick in which phosphorus (P) is doped is formed, and a silicon nitride (SiN) film 280 about 100 nm thick is also formed.

The silicon nitride (SiN) film 280 and phosphorus-doped polysilicon film 270 are patterned by lithography and RIE to form a gate insulating film made of the silicon oxide (SiO₂) film (not shown) and gate electrodes made of the phosphorus-doped polysilicon film 270.

Then, phosphorus (P), for example, is ion-implanted in the surface of the semiconductor substrate 100 to form a source extension region and drain extension region (neither is shown).

Silicon nitride (SiN) about 70 nm thick is deposited on the entire surface of the semiconductor substrate 100, and gate electrode side walls made of a silicon nitride (SiN) film 310 are formed by RIE on the side surfaces of the phosphorus-doped polysilicon film 270 and silicon nitride (SiN) film 280.

In addition, phosphorus (P), for example, is further ion-implanted in the surface of the semiconductor substrate 100 to form a source region 290 and drain region 300.

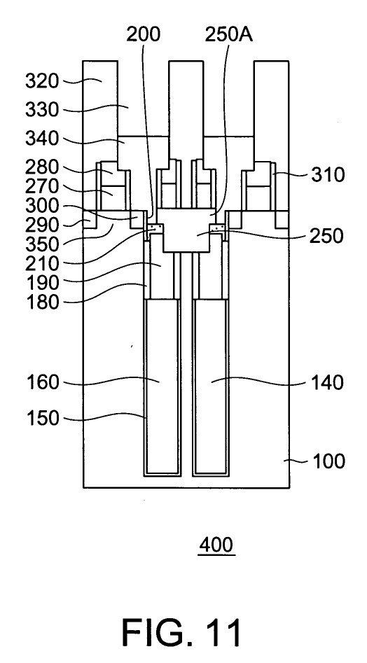

As shown in FIG. 11, a silicon oxide (SiO₂) film 320 about 500 nm thick serving as an interlayer dielectric film is formed on the entire surface of the semiconductor substrate 100, and etched by lithography and RIE to form contact holes 330.

In this step, end portions 250A of the STI film 250, which are in contact with the silicon nitride (SiN) film 200 are partially removed to expose portions of the arsenic-doped polysilicon film 210 formed on the lower surfaces of the end portions 250A of the STI film 250.

After a phosphorus-doped polysilicon film (not shown) is formed by depositing phosphorus-doped polysilicon on the entire surface so as to fill the contact holes 330, and etched by RIE to form surface straps 340 serving as surface connecting layers.

FIG. 11 shows the structure of a memory cell 400 of a trench capacitor type DRAM fabricated by the above method.

The phosphorus-doped polysilicon film 270 as a gate electrode is formed via the silicon oxide (SiO₂) film (not shown) as a gate insulating film on a predetermined region of the semiconductor substrate 100. Additionally, the silicon nitride (SiN) film 280 as a cap insulating film is formed on the phosphorus-doped polysilicon film 270.

The silicon nitride (SiN) films 310 as gate electrode side walls are formed on the side surfaces of the phosphorus-doped polysilicon film 270 and silicon nitride (SiN) film 280.

In the surface portion of the semiconductor substrate 100, the source region 290 and drain region 300 are formed on the two sides of each channel region 350 positioned below the phosphorus-doped polysilicon film 270 as a gate electrode.

The trenches 140 are formed adjacent to the drain regions 300 in the surface portion of the semiconductor substrate. The NO film 150 as a capacitor insulating film is formed on the inner surfaces near the lower portion of each trench 140. Also, the arsenic-doped polysilicon film 160 which is a conductive layer serving as a capacitor electrode is formed to bury the NO film 150.

As described above, the semiconductor substrate 100, NO film 150, and arsenic-doped polysilicon film 160 form a trench capacitor.

The collar oxide film 180 as an insulating film is formed on the inner surface near the upper portion of each trench 140 so as to be adjacent to the NO film 150. The arsenic-doped polysilicon film 190 as a conductive layer is formed to bury the collar oxide film 180. In addition, the arsenic-doped polysilicon film 210 as a conductive film is formed to bury the collar oxide film 180 and arsenic-doped polysilicon film 190.

The surface straps 340 are formed on the surface of the semiconductor substrate 100. Each surface strap 340 is a surface connecting layer for electrically connecting the drain region 300 of the MOS transistor and the conductive layer made of the arsenic-doped polysilicon film 210 in the trench 140.

In the memory cell 400 of the trench capacitor type DRAM having the above structure, an electric current flows between the drain region 300 of each MOS transistor and the arsenic-doped polysilicon film 160 as a capacitor electrode of each trench capacitor via the surface strap 340 and the conductive layers 210 and 190 in order.

The silicon nitride (SiN) film 200 as an impurity diffusion inhibiting film thinner than the collar oxide film 180 is formed on the inner surface of each trench 140 near the interface between the surface strap 340 and arsenic-doped polysilicon 210.

The interface between the surface strap 340 and arsenic-doped polysilicon 210 is positioned at a depth of about 20 nm from the surface of the semiconductor substrate 100. The silicon nitride (SiN) film 200 as an impurity diffusion inhibiting film is formed to a depth of about 30 to 60 nm from this interface.

Note that the STI film 250 for electrically isolating adjacent trench capacitors is formed near the upper end corners of the trenches 140, on the side of the semiconductor substrate 100 where the drain regions 300 are not formed.

The silicon oxide (SiO₂) film 320 as an interlayer dielectric film is formed on the semiconductor substrate 100 and silicon nitride (SiN) film 280.

In this embodiment as described above, the silicon nitride (SiN) film 200 as an impurity diffusion inhibiting film thinner than the collar oxide film 180 is formed on the inner surface of each trench 140 near the interface between the surface strap 340 and the arsenic-doped polysilicon film 210 which forms a conductive layer.

This makes it possible to inhibit arsenic from diffusing into the semiconductor substrate 100 from the arsenic-doped polysilicon film 210 in each trench 140, thereby suppressing a short-channel effect caused by a decrease in gate threshold voltage.

In addition, the area of the interface between the surface strap 340 and arsenic-doped polysilicon film 210 can be made larger than that when the collar oxide film 180 thicker than the silicon nitride (SiN) film 200 is formed near this interface. Accordingly, a resistance produced in the interface between the surface strap 340 and arsenic-doped polysilicon film 210 can be reduced.

### (2) Second Embodiment

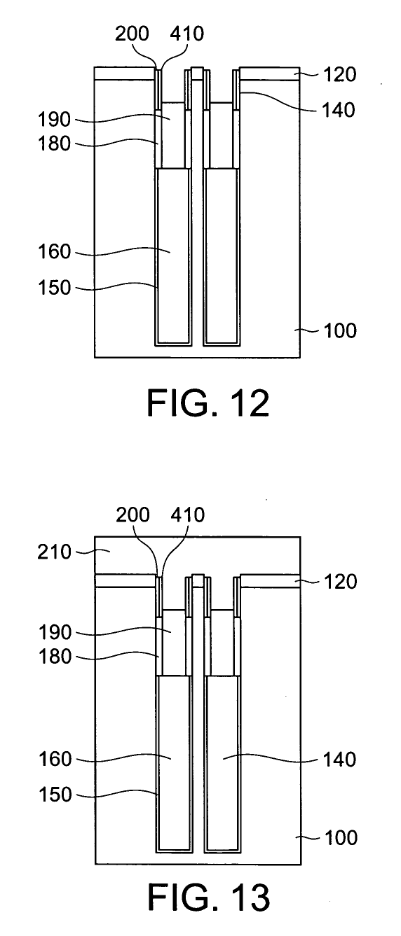

FIGS. 12 to 15 show a semiconductor device fabrication method according to the second embodiment of the present invention. Note that the steps shown in FIGS. 1 to 5 of the first embodiment are the same as in the second embodiment, so an explanation thereof will be omitted.

As shown in FIG. 12, a silicon nitride (SiN) film 200 about, e.g., 2 to 7 nm thick is formed by LPCVD on the entire surfaces of a collar oxide film 180, arsenic-doped polysilicon film 190, and silicon nitride (SiN) film 120. After that, a polysilicon film 410 about 28 to 33 nm thick for protecting the silicon nitride (SiN) film 200 is formed.

Then, the polysilicon film 410 and silicon nitride (SiN) film 200 are etched by RIE to form a silicon nitride (SiN) film 200 serving as an impurity diffusion inhibiting film on the inner surfaces of exposed trenches 140. A polysilicon film 410 is also formed as a protective film.

Note that the silicon nitride (SiN) film 200 is a thin film about 2 to 7 nm thick. Therefore, if the silicon nitride (SiN) film 200 is etched in the step shown in FIG. 6 of the first embodiment, the end portion of the silicon nitride (SiN) film 200 may be removed. In this embodiment, however, the silicon nitride (SiN) film 200 is protected by the polysilicon film 410, so the end portion of the silicon nitride (SiN) film 200 is not removed even when it is etched.

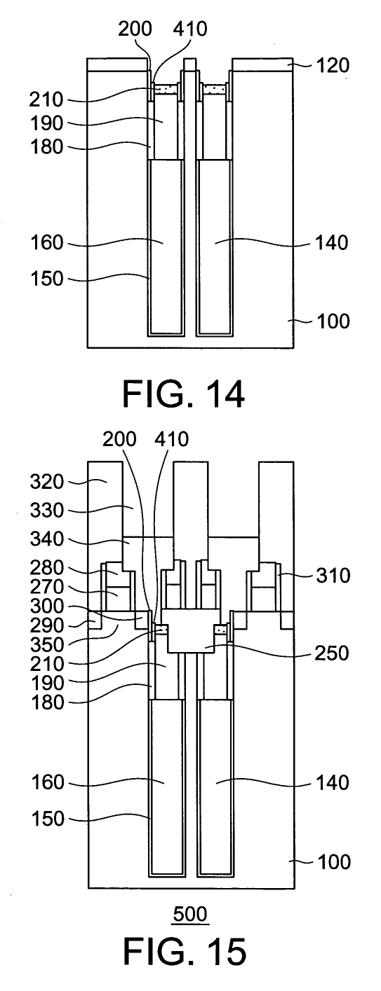

As shown in FIG. 13, an arsenic-doped polysilicon film 210 about 200 nm thick is formed by depositing arsenic-doped polysilicon on the entire surfaces of the silicon nitride (SiN) film 200, polysilicon film 410, arsenic-doped polysilicon film 190, and silicon nitride (SiN) film 120. After that, as shown in FIG. 14, the arsenic-doped polysilicon film 210 is removed by RIE to a depth of about 30 nm from the surface of a semiconductor substrate 100.

Note that the upper portion of the polysilicon film 410 is etched at the same time the arsenic-doped polysilicon 210 is etched. Since, however, the silicon nitride (SiN) film 200 is protected by the polysilicon film 410, etching of the silicon nitride (SiN) film 200 can be suppressed when compared to the first embodiment.

After that, the same steps as shown in FIGS. 8 to 11 of the first embodiment are executed to fabricate a memory cell of a trench capacitor type DRAM. FIG. 15 shows the structure of a memory cell 500 of the trench capacitor type DRAM according to this embodiment. Note that the same reference numerals as in FIG. 11 denote the same elements as shown in FIG. 11, and an explanation thereof will be omitted.

In this embodiment, as shown in FIG. 15, the polysilicon film 410 for protecting the silicon nitride (SiN) film 200 is formed on its surface to a position slightly higher than the interface between a surface strap 340 and the arsenic-doped polysilicon 210.

In this embodiment as described above, the silicon nitride (SiN) film 200 as an impurity diffusion inhibiting film thinner than the collar oxide film 180 is formed on the inner surface of each trench 140 near the interface between the surface strap 340 and the arsenic-doped polysilicon 210 which forms a conductive layer.

This makes it possible to inhibit arsenic from diffusing into the semiconductor substrate 100 from the arsenic-doped polysilicon film 210 in each trench 140, and thereby suppress a short-channel effect caused by a decrease in gate threshold voltage.

### (3) Third Embodiment

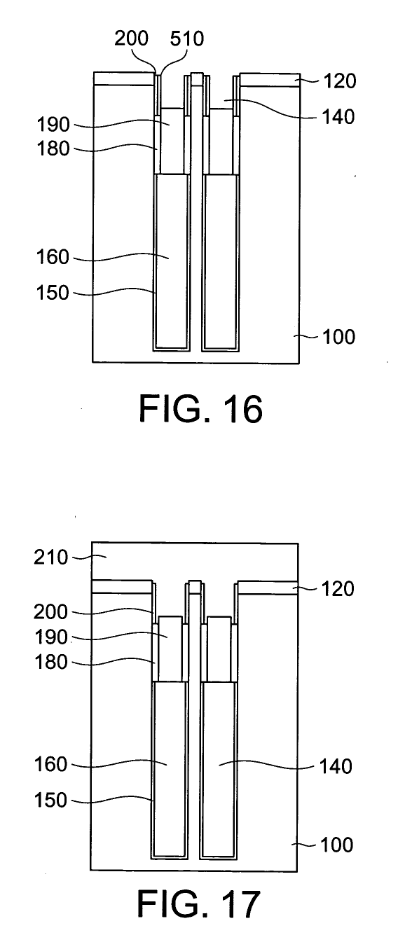

FIGS. 16 to 19 show a semiconductor device fabrication method according to the third embodiment of the present invention. Note that the steps shown in FIGS. 1 to 5 of the first embodiment are the same as in the third embodiment, so an explanation thereof will be omitted.

As shown in FIG. 16, a silicon nitride (SiN) film 200 about, e.g., 2 to 7 nm thick is formed by LPCVD on the entire surfaces of a collar oxide film 180, arsenic-doped polysilicon film 190, and silicon nitride (SiN) film 120. After that, a BSG film 510 as a silicon oxide film in which boron (B) is doped is formed.

Then, the BSG film 510 and silicon nitride (SiN) film 200 are etched by RIE to form a silicon nitride (SiN) film 200 serving as an impurity diffusion inhibiting film on the inner surfaces of exposed trenches 140. In addition, a BSG film 510 for protecting the silicon nitride (SiN) film 200 is formed.

Note that the silicon nitride (SiN) film 200 is a thin film about 2 to 7 nm thick. Therefore, if the silicon nitride (SiN) film 200 is etched in the step shown in FIG. 6 of the first embodiment, the end portion of the silicon nitride (SiN) film 200 may be removed. In this embodiment, however, the silicon nitride (SiN) film 200 is protected by the BSG film 510, so the end portion of the silicon nitride (SiN) film 200 is not removed even when it is etched.

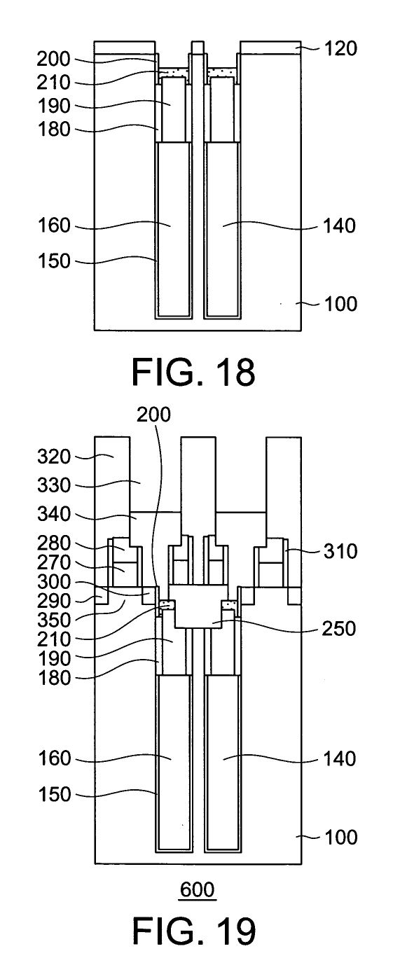

As shown in FIG. 17, after the BSG film 510 is removed by wet etching, an arsenic-doped polysilicon film 210 about 200 nm thick is formed by depositing arsenic-doped polysilicon on the entire surfaces of the collar oxide film 180, arsenic-doped polysilicon film 190, and silicon nitride (SiN) film 120. As shown in FIG. 18, the arsenic-doped polysilicon film 210 is removed by RIE to a depth of about 30 nm from the surface of a semiconductor substrate 100.

After that, the same steps as shown in FIGS. 8 to 11 of the first embodiment are executed to fabricate a memory cell of a trench capacitor type DRAM. FIG. 19 shows the structure of a memory cell 600 of the trench capacitor type DRAM according to this embodiment. Note that this structure is the same as the memory cell 400 of the trench capacitor type DRAM according to the first embodiment shown in FIG. 11, so an explanation thereof will be omitted.

In this embodiment, as in the first embodiment, the silicon nitride (SiN) film 200 as an impurity diffusion inhibiting film thinner than the collar oxide film 180 is formed on the inner surface of each trench 140 near the interface between a surface strap 340 and the arsenic-doped polysilicon 210 which forms a conductive layer.

This makes it possible to inhibit arsenic from diffusing into the semiconductor substrate 100 from the arsenic-doped polysilicon film 210 in each trench 140, thereby suppressing a short-channel effect caused by a decrease in gate threshold voltage.

Also, in this embodiment, no polysilicon film 410 for protecting the silicon nitride (SiN) film 200 is formed unlike in the second embodiment, so the area of the interface between the surface strap 340 and arsenic-doped polysilicon film 210 can be made larger than that in the second embodiment. Accordingly, a resistance produced in the interface between the surface strap 340 and arsenic-doped polysilicon film 210 can be made lower than that in the second embodiment.

### (4) Fourth Embodiment

FIGS. 20 to 26 show a semiconductor device fabrication method according to the fourth embodiment of the present invention. Note that the step shown in FIG. 1 of the first embodiment is the same as in the fourth embodiment, so an explanation thereof will be omitted.

As shown in FIG. 20, after a BSG film 130 is removed by wet etching, a polysilicon film 610 about 16 nm thick and a silicon nitride (SiN) film 620 about 10 nm thick are sequentially formed on the entire surfaces of a semiconductor substrate 100 and silicon nitride (SiN) film 120 by LPCVD. Subsequently, the silicon nitride (SiN) film 620 is coated with a resist material so as to fill trenches 140, thereby forming a resist film 630.

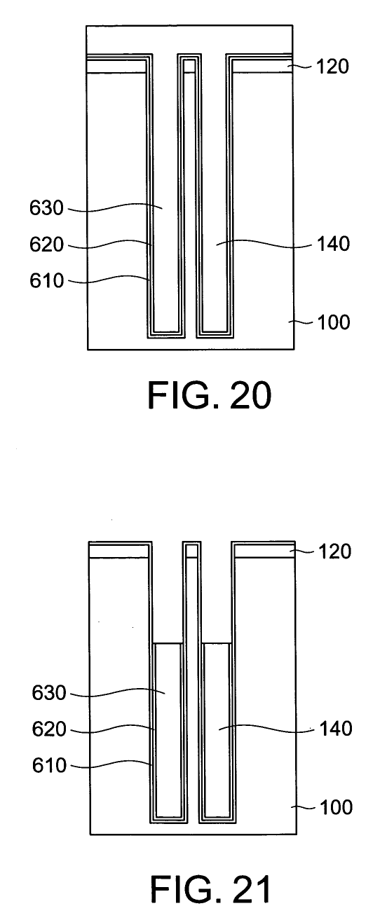

As shown in FIG. 21, the resist film 630 is etched away by CDE (Chemical Dry Etching) to a depth of about 1.3 nm from the surface of the semiconductor substrate 100. Then, the exposed silicon nitride (SiN) film 620 is removed by CDE.

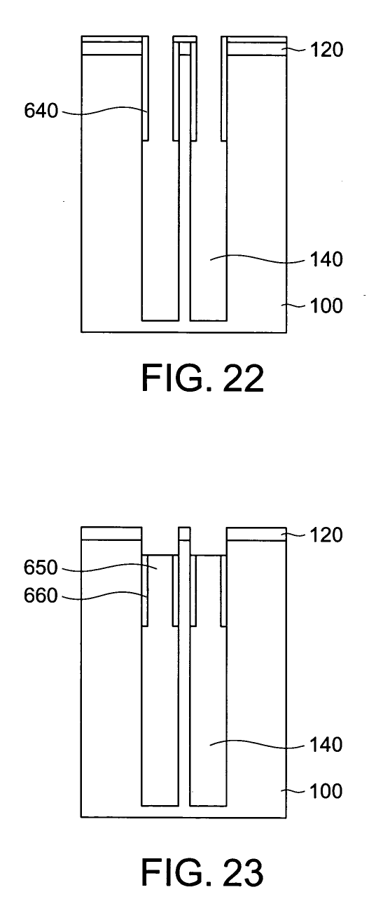

As shown in FIG. 22, the resist film 630 remaining in the lower portions of the trenches 140 is removed by wet etching. After that, the exposed polysilicon film 610 is oxidized in a high-temperature furnace at about 950° C. to form a silicon oxide (SiO₂) film 640 about 45 nm thick.

After the silicon nitride (SiN) film 620 remaining in the lower portions of the trenches 140 is removed by wet etching, the polysilicon film 610 exposed by the removal of the silicon nitride (SiN) film 620 is removed by CDE.

As shown in FIG. 23, the semiconductor substrate 100 and silicon oxide (SiO₂) film 640 are coated with a resist material so as to fill the trenches 140, thereby forming a resist film 650. The resist film 650 is then removed by CDE to a depth of about 60 nm from the surface of the semiconductor substrate 100.

A collar oxide film 660 is formed by removing the exposed silicon oxide (SiO₂) film 640 by wet etching.

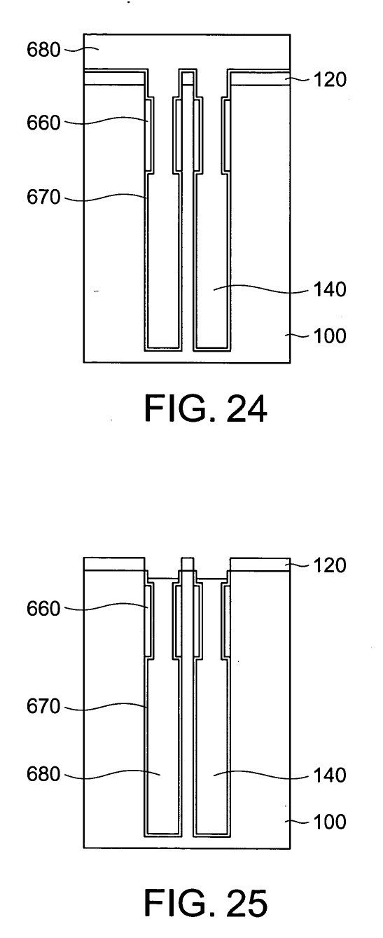

As shown in FIG. 24, after the resist film 650 remaining in the trenches 140 is removed by wet etching, an NO film 670 about 5 nm thick is formed by LPCVD on the inner surfaces of the trenches 140, on the surface of the collar oxide film 660, and on the entire surface of the silicon nitride (SiN) film 120. In addition, an arsenic-doped polysilicon film 680 about 200 nm thick is formed by depositing arsenic-doped polysilicon on the entire surface of the NO film 670.

As shown in FIG. 25, the arsenic-doped polysilicon film 680 is removed by RIE to a depth of about 30 nm from the surface of the semiconductor substrate 100, and the NO film 670 formed on the surface of the silicon nitride (SiN) film 120 is removed by wet etching.

After that, the same steps as in FIGS. 8 to 11 of the first embodiment are executed to fabricate a memory cell of a trench capacitor type DRAM.

In this embodiment as described above, since the NO film 670 is formed on the entire inner surfaces of the trenches 140, the capacitor insulating film and impurity diffusion inhibiting film can be formed at the same time. Accordingly, the number of steps can be reduced because it is unnecessary to separately form the capacitor insulating film and impurity diffusion inhibiting film unlike in the first to third embodiments.

Also, when arsenic-doped polysilicon is divisionally buried in the trenches 140 three times as in the first to third embodiments, native oxide films are formed between the arsenic-doped polysilicon films 160, 190, and 210. However, when the arsenic-doped polysilicon film 680 is formed by burying arsenic-doped polysilicon in the trenches 140 at once as in this embodiment, no native oxide film is formed, and the number of steps can be made smaller than those in the first to third embodiments.

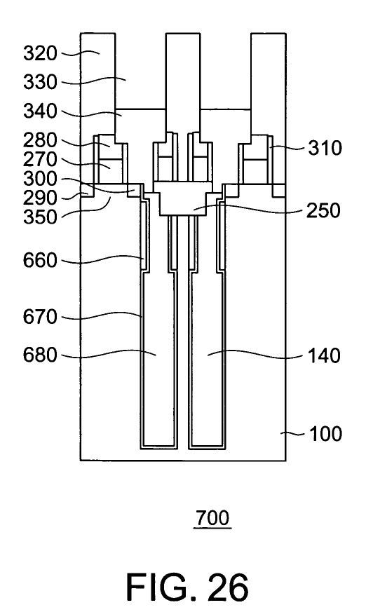

FIG. 26 shows the structure of a memory cell 700 of the trench capacitor type DRAM according to this embodiment. Note that the same reference numerals as in FIG. 11 denote the same elements as shown in FIG. 11, and an explanation thereof will be omitted. As shown in FIG. 26, in the memory cell 700 of the trench capacitor type DRAM, the capacitor insulating film and impurity diffusion inhibiting film are formed by the same NO film 670.

In this embodiment as described above, a silicon nitride (SiN) film 200 as an impurity diffusion inhibiting film thinner than a collar oxide film 180 is formed on the inner surface of each trench 140 near the interface between a surface strap 340 and an arsenic-doped polysilicon 210 which forms a conductive layer.

This makes it possible to inhibit arsenic from diffusing into the semiconductor substrate 100 from the arsenic-doped polysilicon film 210 in each trench 140, thereby suppressing a short-channel effect caused by a decrease in gate threshold voltage.

Also, the area of the interface between the surface strap 340 and arsenic-doped polysilicon film 210 can be made larger than that when the collar oxide film 180 thicker than the silicon nitride (SiN) film 200 is formed near the interface between the surface strap 340 and arsenic-doped polysilicon film 210. Accordingly, a resistance produced in the interface between the surface strap 340 and arsenic-doped polysilicon film 210 can be reduced.

The above embodiment can suppress the short-channel effect, and reduce the resistance produced in the interface between the surface strap formed on the surface of the semiconductor substrate and the conductive layer formed in the trench.

Note that the above embodiments are merely examples and do not limit the present invention. For example, as the impurity diffusion inhibiting film, it is also possible to use a silicon nitride (SiN) film, a silicon oxide (SiO₂) film, an oxide film mainly containing, e.g., aluminum (Al), tantalum (Ta), titanium (Ti), strontium (Sr), hafnium (Hf), or zirconium (Zr), or a stacked film formed by stacking these materials.

What is claimed is:

1. A semiconductor device comprising:
a gate electrode formed via a gate insulating film selectively formed on a predetermined region of a semiconductor substrate;
a source region and drain region formed in a surface portion of said semiconductor substrate on two sides of a channel region positioned below said gate electrode;
a capacitor insulating film formed in the surface portion of said semiconductor substrate to cover an inner surface near a bottom portion of a trench formed adjacent to one of said source region and drain region;
a capacitor electrode formed to be buried in said trench covered with said capacitor insulating film;
an insulating film formed to cover an inner surface of said trench, which is not covered with said capacitor insulating film;
a conductive layer containing a predetermined impurity and formed in said trench so as to be buried in a portion covered with said insulating film on said capacitor electrode;
a surface connecting layer formed on the surface of said semiconductor substrate to electrically connect said conductive layer and one of said source region and drain region; and
an impurity diffusion inhibiting film formed to cover the inner surface of said trench to a predetermined depth from an interface between said surface connecting layer and conductive layer, and having a film thickness smaller than that of said insulating film.

2. A device according to claim 1, wherein the film thickness of said impurity diffusion inhibiting film is 2 to 7 nm.

3. A device according to claim 1, wherein the film thickness of said insulating film is 35 to 45 nm.

4. A device according to claim 1, further comprising a protective film formed between said conductive film and impurity diffusion inhibiting film to cover a portion of said impurity diffusion inhibiting film.

5. A device according to claim 4, wherein a film thickness of said protective film is 28 to 43 nm.

6. A device according to claim 1, further comprising an element isolation insulating film formed near a corner of said trench, on a side of an inner surface of said trench where said source region and drain region are not formed, and on a side of the surface of said semiconductor substrate.

7. A semiconductor device comprising:
a gate electrode formed via a gate insulating film selectively formed on a predetermined region of a semiconductor substrate;
a source region and drain region formed in a surface portion of said semiconductor substrate on two sides of a channel region positioned below said gate electrode;
an insulating film formed in the surface portion of said semiconductor substrate to cover an inner surface of a trench formed adjacent to one of said source region and drain region, except for a portion near the surface of said semiconductor substrate and a portion near a bottom portion of said trench;
an impurity diffusion inhibiting film formed to cover the inner surface of said trench and said insulating film, and having a film thickness smaller than that of said insulating film;
a conductive layer containing a predetermined impurity and formed to be buried in said trench in which said impurity diffusion inhibiting film is formed; and
a surface connecting layer formed on the surface of said semiconductor substrate to electrically connect said conductive layer and one of said source region and drain region.

8. A device according to claim 7, wherein the film thickness of said impurity diffusion inhibiting film is 2 to 7 nm.

9. A device according to claim 7, wherein the film thickness of said insulating film is 35 to 45 nm.

10. A device according to claim 7, further comprising an element isolation insulating film formed near a corner of said trench, on a side of an inner surface of said trench where said source region and drain region are not formed, and on a side of the surface of said semiconductor substrate.

11. A semiconductor device fabrication method comprising:
forming a trench by removing a desired region of a surface portion of a semiconductor substrate;
forming a capacitor insulating film to cover an inner surface near a bottom portion of the trench;
forming a film by depositing a conductive material containing a first impurity so as to fill the trench covered with the capacitor insulating film, thereby forming a capacitor electrode;
forming an insulating film so as to cover an inner surface of the trench, which is not covered with the capacitor insulating film;
forming, in the trench, a film by depositing the conductive material containing a second impurity so as to fill a portion covered with the insulating film on the capacitor electrode, thereby forming a first conductive layer;
forming an impurity diffusion inhibiting film having a film thickness smaller than that of the insulating film, so as to cover an inner surface of the trench near the surface of the semiconductor substrate;
forming, in the trench, a film by depositing the conductive material containing a third impurity so as to fill a portion covered with the impurity diffusion inhibiting film on the first conductive layer, thereby forming a second conductive layer;
forming a gate electrode on a predetermined region of the semiconductor substrate via a gate insulating film;
forming a source region and drain region in the surface portion of the semiconductor substrate, such that one of the source region and drain region is adjacent to the trench; and
forming, on the surface of the semiconductor substrate, a surface connecting layer which electrically connects the second conductive layer and one of the source region and drain region.

12. A method according to claim 11, wherein when the impurity diffusion inhibiting film is formed, a protective film is so formed as to cover the impurity diffusion inhibiting film after the impurity diffusion inhibiting film is formed.

13. A method according to claim 11, wherein when the impurity diffusion inhibiting film is formed, after a protective film is so formed as to cover a surface of the impurity diffusion inhibiting film, the impurity diffusion inhibiting film is formed, and the protective film is removed thereafter.

14. A method according to claim 11, further comprising, forming an element isolation insulating film near a corner of the trench near the surface of the semiconductor substrate, after the second conductive layer is formed.

15. A semiconductor device fabrication method comprising:
forming a trench by removing a desired region of a surface portion of a semiconductor substrate;
sequentially forming first and second films so as to cover an inner surface of the trench;
forming a first resist film having a desired height from a bottom portion of the trench by coating a first resist material so as to fill the trench in which the first and second films are formed;
removing the second film having an exposed surface, and removing the first resist film remaining in the trench;
forming a first insulating film by oxidizing the first film having an exposed surface;
sequentially removing the second and first films remaining in the trench;
forming a second resist film lower than the surface of the semiconductor substrate by coating a second resist material so as to fill the trench in which the first insulating film is formed;
removing the first insulating film having an exposed surface;
removing the second resist film remaining in the trench;
forming a second insulating film having a film thickness smaller than that of the first insulating film, on the inner surface of the trench and on the surface of the first insulating film;
forming a film by depositing a conductive material containing a predetermined impurity so as to fill the trench in which the first and second insulating films are formed, thereby forming a conductive layer;
forming a gate electrode on a predetermined region of the semiconductor substrate via a gate insulating film;
forming a source region and drain region in the surface portion of the semiconductor substrate, such that one of the source region and drain region is adjacent to the trench; and
forming, on the surface of the semiconductor substrate, a surface connecting layer which electrically connects the conductive layer and one of the source region and drain region.

16. A method according to claim 15, further comprising, forming an element isolation insulating film near a corner of the trench near the surface of the semiconductor substrate, after the conductive layer is formed.
